(19) United States
(12) Patent Application Publication
(10) Pub. No.: US 2024/0234336 A1
(43) Pub. Date: Jul. 11, 2024

(54) ELECTRONIC DEVICE AND METHOD FOR MANUFACTURING THE SAME

(71) Applicant: JCET STATS ChipPAC Korea Limited, Incheon (KR)

(72) Inventors: DoYeon PARK, Gyeonggi-do (KR); SangJun PARK, Busan (KR); JiYeon KIM, Incheon (KR)

(21) Appl. No.: 18/395,650

(22) Filed: Dec. 25, 2023

(30) Foreign Application Priority Data
Jan. 5, 2023 (CN) 202310014572.4

(51) Int. Cl. H01L 23/552; H01L 21/56; H01L 23/498

(52) U.S. Cl. CPC H01L 23/552; H01L 21/565; H01L 23/49816

(57) ABSTRACT

An electronic device and a method for manufacturing an electronic device are provided. The electronic device includes: a substrate; at least one electronic component mounted on the substrate; an encapsulant layer formed on the substrate and encapsulating the at least one electronic component; at least one metal bar mounted on the substrate and protruding above the encapsulant layer; and a shielding layer formed over the encapsulant layer, wherein the shielding layer is in contact with the at least one metal bar; wherein the encapsulant layer includes at least one trench each being adjacent to and extending around one of the at least one metal bar to expose an upper portion of a lateral surface of the metal bar from the encapsulant layer.

### TECHNICAL FIELD

The present application generally relates to semiconductor technology, and more particularly, to an electronic device and a method for manufacturing an electronic device.

### BACKGROUND OF THE INVENTION

Consumer electronic devices may include lots of integrated circuits (ICs) and other electrical devices. For example, a wireless communication device, such as a mobile phone, may include logic chips, memory chips, integrated passive devices, radio frequency (RF) filters, sensors, heat sinks, or antennas mounted on a single circuit board or substrate. However, high speed digital and RF electronic devices included in the wireless communication device may serve as a source of electromagnetic waves, which may interrupt, obstruct, or otherwise degrade or limit the effective performance of other circuits in the device.

Therefore, a need exists for reducing electromagnetic interference (EMI) in the electronic device.

### SUMMARY OF THE INVENTION

An objective of the present application is to provide an electronic device with reduced electromagnetic interference and a method for manufacturing such electronic device.

According to an aspect of the present application, an electronic device is provided. The electronic device may include: a substrate; at least one electronic component mounted on the substrate; an encapsulant layer formed on the substrate and encapsulating the at least one electronic component; at least one metal bar mounted on the substrate and protruding above the encapsulant layer; and a shielding layer formed over the encapsulant layer, wherein the shielding layer is in contact with the at least one metal bar; wherein the encapsulant layer includes at least one trench each being adjacent to and extending around one of the at least one metal bar to expose an upper portion of a lateral surface of the metal bar from the encapsulant layer.

According to another aspect of the present application, a method for manufacturing an electronic device is provided. The method may include: providing a substrate with at least one electronic component and at least one metal bar mounted thereon; forming an encapsulant layer on the substrate to encapsulate the at least one electronic component and the at least one metal bar and expose a top surface of each of the at least one metal bar; forming at least one trench adjacent to and around the at least one metal bar, respectively, to expose an upper portion of a lateral surface of each of the at least one metal bar from the encapsulant layer; and forming a shielding layer over the encapsulant layer and the at least one metal bar, wherein the shielding layer is in contact with the at least one metal bar.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A is a cross-sectional view of an electronic device.

FIG. 1B is a perspective view of the electronic device shown in FIG. 1A.

FIG. 2A is a cross-sectional view of an electronic device according to an embodiment of the present application.

FIG. 2B is a perspective view of the electronic device shown in FIG. 2A.

FIGS. 3A-3D are enlarged views illustrating a portion of the electronic device shown in FIG. 2A according to different embodiments of the present application.

FIGS. 4A to 4F illustrate cross-sectional views of a process for making an electronic device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

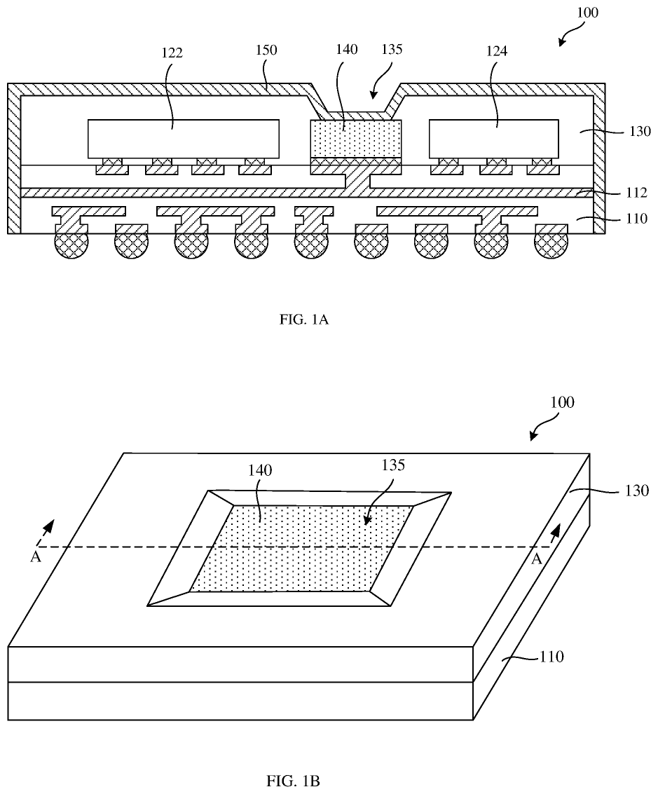

FIGS. 1A and 1B illustrate an electronic device 100, in which a conformal electromagnetic interference (EMI) shielding layer 150 is formed to prevent electromagnetic noises radiated by high frequency components. FIG. 1A is a cross-sectional view of the electronic device 100 along a section line AA shown in FIG. 1B, and FIG. 1B is a perspective view of the electronic device 100, in which the EMI shielding layer 150 is omitted to show the internal components more clearly.

As shown in FIG. 1A, the electronic device 100 includes a substrate 110 and two electronic components 122 and 124 mounted thereon. One or both of the electronic components 122 and 124 may include high speed digital and RF electronic devices, which may radiate electromagnetic noises to the outside. Thus, a metal bar 140 is formed between the two electronic components 122 and 124 to reduce electromagnetic interferences therebetween. An encapsulant 130 is formed on the substrate 110 and encapsulates the electronic components 122 and 124. The EMI shielding layer 150 is formed on the encapsulant 130 and should be coupled to a reference node or potential (for example, a ground layer 112 in the substrate 110) via the metal bar 140. As the metal bar 140 is lower than and encapsulated by the encapsulant 130, a trench 135 is first formed in the encapsulant 130 to expose a top surface of the metal bar 140, and then the EMI shielding layer 150 is formed on the encapsulant 130 and the exposed surface of the metal bar 140.

However, as shown in FIGS. 1A and 1B, the trench 135 can only expose a portion of the top surface of the metal bar 140. EMI leakages still exist in the electronic device 100, and the heat generated by the electronic components 122 and 124 cannot be effectively dissipated.

To address at least one of the above problems, an electronic device is provided in an aspect of the present application. In the device, an encapsulant layer is formed on a substrate and encapsulates at least one electronic component mounted on the substrate. A metal bar is also mounted on the substrate and protrudes above the encapsulant layer. The encapsulant layer includes a trench which is adjacent to and extends around the metal bar to expose an upper portion of a lateral surface of the metal bar from the encapsulant layer. Thus, a shielding layer formed over the encapsulant layer can be in contact with the top surface and exposed lateral surface of the metal bar. As the contact area between the shielding layer and the metal bar increases, the EMI leakages within the electronic device can be reduced, and the heat generated by the electronic component can be effectively dissipated.

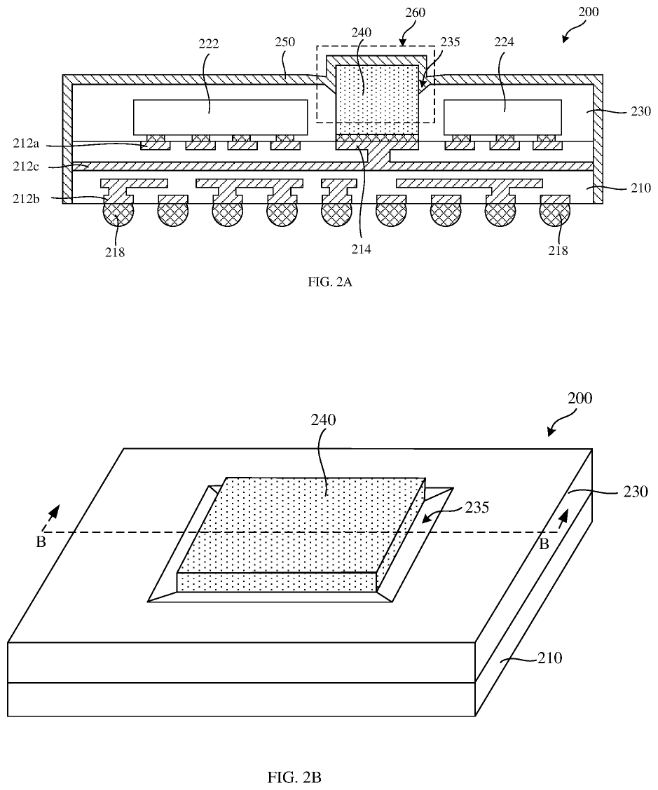

FIGS. 2A and 2B illustrate an electronic device 200 according to an embodiment of the present application. FIG. 2A is a cross-sectional view of the electronic device 200 along a section line BB shown in FIG. 2B, and FIG. 2B is a perspective view of the electronic device 200.

As shown in FIGS. 2A and 2B, the electronic device 200 includes a substrate 210. The substrate 210 can be a printed circuit board (PCB), laminate interposer, wafer-form, strip interposer, leadframe, or another suitable substrate that can support and interconnect various electronic components. The substrate 210 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The substrate 210 can also be a multi-layer flexible laminate, ceramic, copper clad laminate, or glass. In some embodiments, the substrate 210 may include one or more insulating or passivation layers, one or more conductive vias formed through the insulating layers, and one or more conductive layers formed over or between the insulating layers.

In some embodiments, the substrate 210 may include a plurality of wiring layers, which define pads, traces and plugs through which electrical signals or voltages can be distributed horizontally and vertically across the substrate 210. For example, as shown in FIG. 2A, the substrate 210 includes a top wiring layer 212a, a bottom wiring layer 212b, and a ground (GND) layer 212c. The top wiring layer 212a may include a plurality of contact pads on which one or more electronic components are to be mounted, while the bottom wiring layer 212b may also include a plurality of contact pads on which one or more bumps 218 are mounted. When the electronic device 200 is assembled with other electronic devices in an electronic product or an electronic system, the ground layer 212c can be electrically coupled to the ground or other voltage reference to serve as ground for the electronic device 200. The wiring layers may include one or more of Al, Cu, Sn, Ni, Au, Ag, or any other suitable electrically conductive material. It could be appreciated that, the wiring layers may be implemented in various structures and types, but aspects of the present application are not limited to the above example.

At least two electronic components 222 and 224 are mounted on the contact pads of the top wiring layer 212a. The electronic components 222 and 224 may include any of a variety of types of semiconductor dice, semiconductor packages, or discrete devices. For example, the electronic components 222 and 224 may include a digital signal processor (DSP), a microcontroller, a microprocessor, a network processor, a power management processor, an audio processor, a video processor, an RF circuit, a wireless baseband system on chip (SoC) processor, a sensor, a memory controller, a memory device, an application specific integrated circuit, etc. The electronic components 222 and 224 can be mounted on the substrate 210 using any suitable surface mounting techniques.

In some embodiments, the electronic components 222 and 224 may include any component that is configured to provide several mobile functionalities and capabilities, including but not limited to, positioning functionality, wireless connectivity functionality (e.g., wireless communication) and/or cellular connectivity functionality (e.g., cellular communication). However, the electronic component 222 and the electronic component 224 may have different requirements on EMI shielding, due to their respective functions in the electronic device 200. For example, the electronic component 222 may contain devices or circuits that generate electromagnetic interferences (EMI). In an example, the electronic component 222 may include a transceiver having a transmitting (Tx) circuit, a receiving (Rx) circuit, and/or AD/DA convertors, and the electronic component 224 may include a power amplifier, a filter, a switch, and/or a low noise amplifier (LNA) to provide a radio frequency front end (RFFE) functionality. As the transceiver always use a voltage-controlled oscillator (VCO) circuit to produce oscillating signals (waveforms) with variable frequencies, electromagnetic interferences generated by the VCO circuit may leak into its neighboring electrical components, thereby degrading the performance of the neighboring electrical components.

In order to obstruct the electromagnetic interferences, at least one metal bar 240 is formed between the electronic component 222 and the electronic component 224. The metal bar 240 is mounted on a ground pad 214 in the top wiring layer 212a, and the ground pad 214 is connected to the ground layer 212c in the substrate 210. The metal bar 240 may include one or more of Cu, Al, Sn, Ni, Au, Ag, or other suitable electrically conductive material. In an example, the metal bar 240 is a copper pillar, but aspects of the present disclosure are not limited thereto.

An encapsulant layer 230 is formed on the substrate 210 to cover the electronic components 222 and 224 and surround the metal bar 240. In some embodiments, the encapsulant layer 230 may be made of a polymer composite material such as epoxy resin with filler, epoxy acrylate with filler, or polymer with proper filler, for example.

As shown in FIG. 2A, the metal bar 240 protrudes above the encapsulant layer 230. In other words, the metal bar 240 is higher than the encapsulant layer 230 and the electronic components 222 and 224. In some embodiments, the metal bar 240 may be 1.001, 1.01, 1.1, 1.2, 1.3 or any other times the height of the encapsulant layer 230, but is generally less than twice the height of the encapsulant layer 230, such that an upper portion of the metal bar 240 is exposed from the encapsulant layer 230. In addition, a trench 235 is formed in the encapsulant layer 230. The trench 235 is adjacent to the metal bar 240, and extends around the metal bar 240 to further expose an additional portion of the lateral surface of the metal bar 240 from the encapsulant layer 230.

Furthermore, a shielding layer 250 is formed on the encapsulant layer 230 to shield EMI induced to or generated by the electronic device 200. In some embodiments, the shielding layer 250 can be made of a conductive material such as copper, aluminum, iron, or any other suitable material for electromagnetic interference shielding. The shielding layer 250 follows the shapes and/or contours of the substrate 210, the encapsulant layer 230 and the metal bar 240. That is, the shielding layer 250 may cover the lateral surface of the substrate 210, the top and lateral surfaces of the encapsulant layer 230, and the top and exposed lateral surface of the metal bar 240. As a lateral surface of the GND layer 212c is exposed from the lateral surface of the substrate 210, the shielding layer 250 may also be coupled to ground via the ground layer 212c.

Referring to the perspective view of the electronic device 200 shown in FIG. 2B, the EMI shielding layer 250 is omitted to show the metal bar 240 more clearly. The metal bar 240 protrudes above the encapsulant layer 230 to expose its entire top surface and the upper portion of lateral surface. As can be seen, the exposed top surface of the metal bar 240 has a rectangular shape, and the trench 235 following the contour of the metal bar 240 may also have a rectangular shape. The trench 235 formed in the encapsulant layer 230 further exposes an additional portion of the lateral surface of the metal bar 240. Compared with the exposed portion of the top surface of the metal bar 140 shown in FIG. 1B, the exposed surface of the metal bar 240 significantly increases, and accordingly the contact area between the metal bar 240 and the shielding layer 250 formed thereon can significantly increase. Thus, the EMI leakage (for example, the electromagnetic interferences generated by the VCO circuit) from the electronic component 222 to the electronic component 224 can be reduced, and the heat generated by the electronic components 222 and 224 can be effectively dissipated.

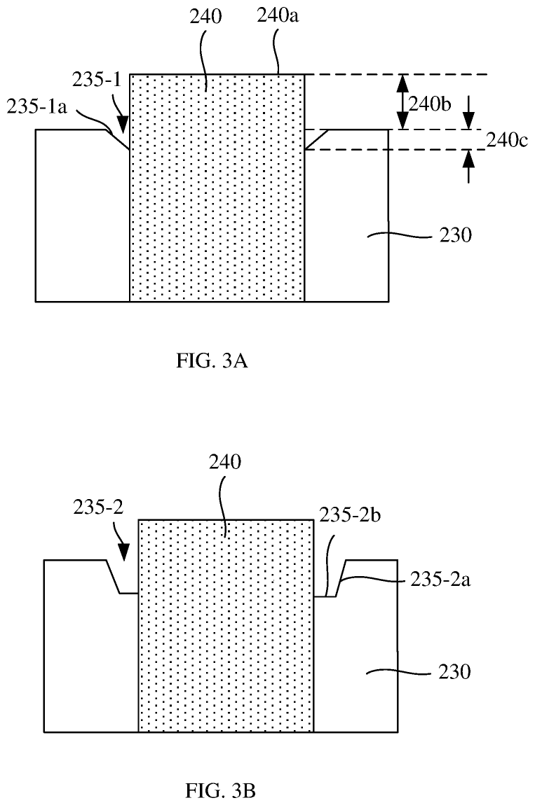

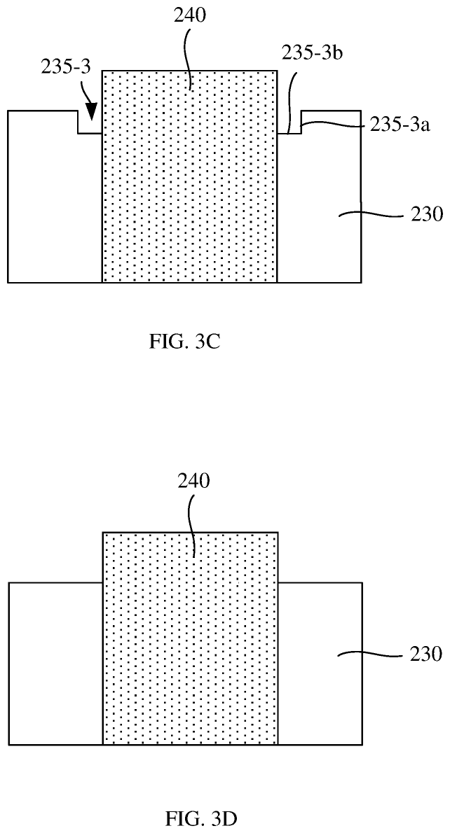

FIGS. 3A-3C illustrate enlarged views of a portion 260 of the electronic device 200 shown in FIG. 2A according to different embodiments of the present application, in which the EMI shielding layer 250 is also omitted to show the internal components more clearly.

As shown in FIG. 3A, the metal bar 240 protrudes above the encapsulant layer 230 to expose an entire top surface 240a and an upper portion 240b of the lateral surface of the metal bar 240 from the encapsulant layer 230. A trench 235-1 is formed in the encapsulant layer 230 and extends around the metal bar 240. The trench 235-1 includes a sloping surface 235-1a that slopes towards and terminates at the metal bar 240. In this way, less encapsulant material needs to be removed when forming the trench 235-1. A depth 240c of the trench 235-1 may range from 3% to 70% of the height of the encapsulant layer 230, for example, 5%, 10%, 20%, 30%, 40%, 50% or 60% of the height of the encapsulant layer 230.

Referring to FIG. 3B, in another embodiment, a groove 235-2 is formed in the encapsulant layer 230 and extends around the metal bar 240. The groove 235-2 may include a lateral surface 235-2a and a bottom surface 235-2b. The lateral surface 235-2a may slope towards the metal bar 240, and the bottom surface 235-2b may be substantially parallel to the top surface of the metal bar 240. Compared with the trench 235-1 shown in FIG. 3A, the groove 235-2 can accommodate more shielding materials, thereby further enhancing the shielding effect of the EMI shielding layer 250.

Referring to FIG. 3C, in a further embodiment, a groove 235-3 is formed in the encapsulant layer 230 and extends around the metal bar 240. The groove 235-3 may include a lateral surface 235-3a and a bottom surface 235-3b. Different from the sloping lateral surface 235-2a shown in FIG. 3B, the lateral surface 235-3a shown in FIG. 3C may be substantially perpendicular to the top surface of the metal bar 240.

It could be understood that the shapes and configurations of the grooves shown in FIGS. 3A-3C are only for illustrative purpose, and aspects of the present application are not limited thereto. In another embodiment as shown in FIG. 3D, there may be no groove formed in the encapsulant layer 230 and around the metal bar 240. That is, the top surface of the encapsulant layer 230 is flat and is substantially parallel to the top surface of the metal bar 240. Thus, the process for making the electronic device can be simplified.

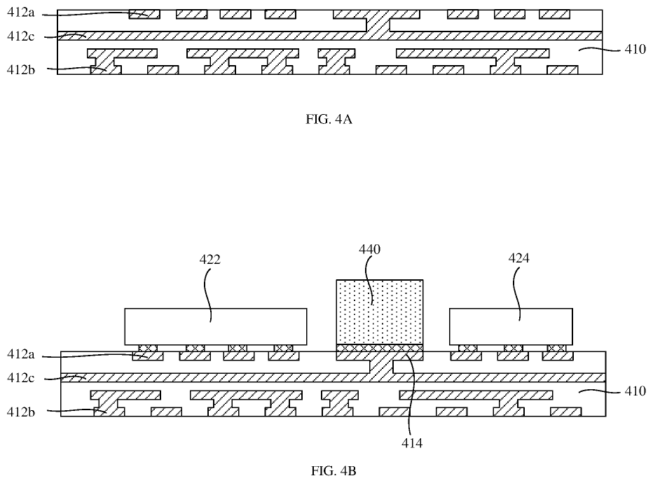

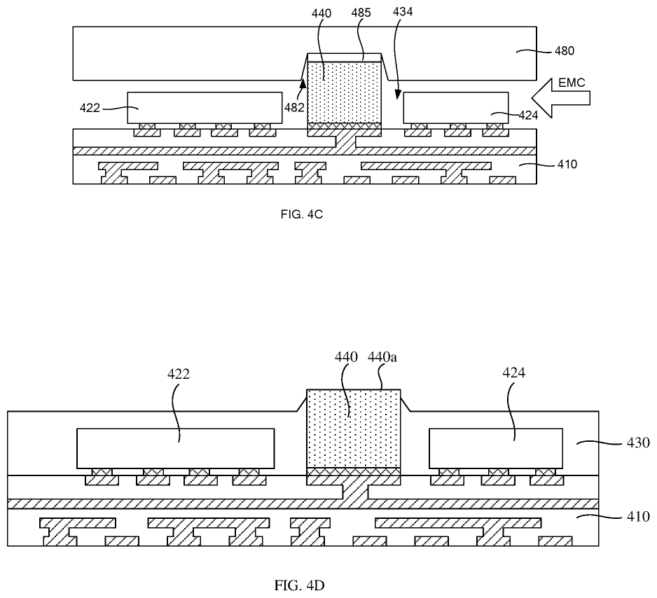

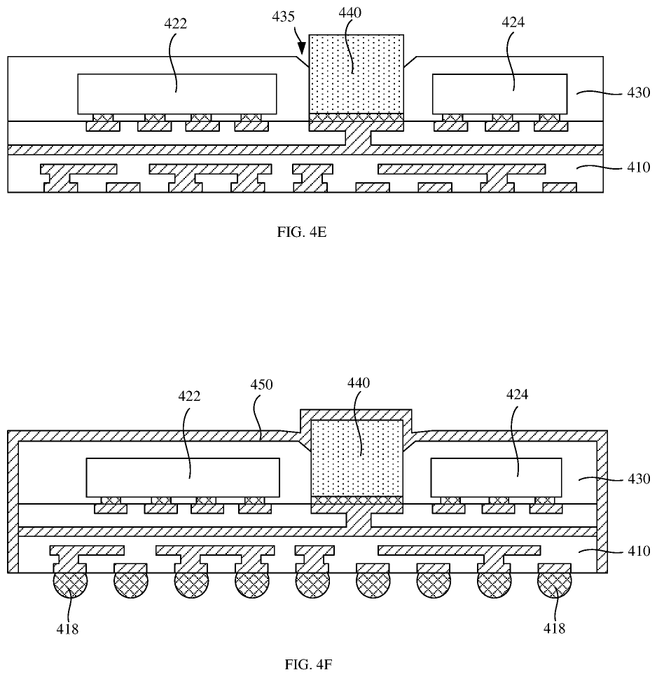

FIGS. 4A to 4F illustrate cross-sectional views of a process for making an electronic device according to an embodiment of the present application. For example, the process can be used to make the electronic device 200 shown in FIGS. 2A and 2B.

As shown in FIG. 4A, a substrate 410 is provided. The substrate 410 may be a printed circuit board (PCB), laminate interposer, wafer-form, strip interposer, leadframe, or another suitable substrate that can support and interconnect various electronic components. The substrate 410 may include a plurality of wiring layers, which define pads, traces and plugs through which electrical signals or voltages can be distributed horizontally and vertically across the substrate 410. For example, as shown in FIG. 4A, the substrate 410 includes a top wiring layer 412a, a bottom wiring layer 412b, and a ground (GND) layer 412c. The top wiring layer 412a may include a plurality of contact pads on which one or more electronic components are to be mounted, while the bottom wiring layer 412b may also include a plurality of contact pads on which one or more bumps are to be mounted. When the electronic device to be formed is assembled with other electronic devices in an electronic product or an electronic system, the ground layer 412c can be electrically coupled to the ground or other voltage reference to serve as a ground for the electronic device.

Next, as shown in FIG. 4B, at least one electronic component and at least one metal bar is mounted on the substrate 410. In the example shown in FIG. 4B, at least two electronic components 422 and 424 are mounted on the contact pads of the top wiring layer 412a. In some embodiments, the electronic components 422 and 424 may include any component that is configured to provide several mobile functionalities and capabilities, including but not limited to, positioning functionality, wireless connectivity functionality (e.g., wireless communication) and/or cellular connectivity functionality (e.g., cellular communication). However, the electronic component 422 and the electronic component 424 may have different requirements on EMI shielding, due to their respective functions in the electronic device. For example, the electronic component 422 may contain devices or circuits that generate electromagnetic interference, and the electronic component 424 may contain devices or circuits that are susceptible to electromagnetic interference. Furthermore, at least one metal bar 440 is formed between the electronic component 422 and the electronic component 424. The metal bar 440 is mounted on a ground pad 414 in the top wiring layer 412a, and the ground pad 414 is connected to the ground layer 412c in the substrate 410. The metal bar 440 may be higher than the electronic components 422 and 424, for example, 1.1, 1.2, 1.3, 1.4, 1.5, 1.6 or any other times the height of the electronic components 422 and 424.

In an example, solder paste may be deposited or printed onto contact pads of the top wiring layer 412a where the electronic components 422 and 424 and the metal bar 440 are to be surface mounted. The solder paste can be dispensed by jet printing, laser printing, pneumatically, by pin transfer, using a photoresist mask, by stencil-printing, or by another suitable process. Then, the electronic components 422 and 424 and the metal bar 440 may be mounted on the substrate 410 with terminals in contact with and over the solder paste. The solder paste may be reflowed to mechanically and electrically couple the electronic components 422 and 424 and the metal bar 440 to the contact pads of the top wiring layer 412a. However, the present application is not limited to the above example. In some other examples, the electronic components 422 and 424 and the metal bar 440 can be mounted onto the substrate 410 using other suitable surface mounting techniques, and/or in different steps.

As shown in FIG. 4C and FIG. 4D, an encapsulant layer 430 is formed on the substrate 410 to encapsulate the electronic components 422 and 424 and the metal bar 440 and expose a top surface 440a of the metal bar 440.

In some embodiments, the encapsulant layer 430 is formed using a film assisted molding (FAM) technique. For example, as shown in FIG. 4C, a mold chase 480 is provided. The mold chase 480 has a cavity 482 for accommodating the metal bar 440. The cavity 482 may include a sloping lateral surface, such that the metal bar 440 can be easily accommodated into the cavity 482. A film 485 is attached on an inner surface of the cavity 482. For example, the film 485 can be sucked onto the inner surface of the cavity 482. Then, the mold chase 480 is placed over the substrate 410 to form a molding chamber 434 between the mold chase 480 and the substrate 410. The film 485 is sandwiched between the mold chase 480 and the top surface 440a of the metal bar 440, and can follow the three-dimensional form of the cavity 482. Afterwards, an encapsulant material such as an epoxy molding compound (EMC) is injected into the molding chamber 434. After the epoxy molding compound is solidified, the substrate 410 is unloaded from the mold chase 480, and the film 485 is detached from the metal bar 440 to expose the top surface 440a of the metal bar 440. In some embodiments, the film 485 may include a Teflon-based material, and thus can be easily released from the metal bar 440. Accordingly, the top surface 440a of the metal bar 440 can be kept clear of sticky molding compound.

However, the present application is not limited to the above example. In some embodiments, the film 485 can be attached on the top surface 440a of the metal bar 440, and then is sandwiched between the mold chase 480 and the top surface 440a. In some embodiments, the encapsulant layer 430 can be formed by other molding techniques such as compression molding, transfer molding, liquid encapsulant molding, vacuum lamination, spin coating, or paste printing.

Afterwards, as shown in FIG. 4E, a trench 435 is formed in the encapsulant layer 430. The trench 435 is adjacent to and around the metal bar 440 to expose an upper portion of a lateral surface of the metal bar 440 from the encapsulant layer 430.

In some embodiments, a laser ablation process may be employed to form the trench 435 in the encapsulant layer 430. The laser ablation technique can accurately control a depth and shape of the trench to be formed. However, the present application is not limited thereto. In other embodiments, the trench 435 may be formed by an etching process, or any other process known in the art so long as the encapsulant material can be removed. In some embodiments, after forming the trench 435, a cleaning process for removing residuals may further be performed.

More details about configurations of the trench 435 may refer to FIGS. 3A-3C and relevant descriptions in above embodiments, and will not be elaborated herein.

At last, as shown in FIG. 4F, a shielding layer 450 is formed over the encapsulant layer 430 and the metal bar 440. In some embodiments, the shielding layer 450 may be formed using spray coating, plating, sputtering, or any other suitable metal deposition process. The shielding layer 450 can be made of a conductive material such as copper, aluminum, iron, or any other suitable material for electromagnetic interference shielding. The shielding layer 450 follows the shapes and/or contours of the substrate 410, the encapsulant layer 430 and the metal bar 440. That is, the shielding layer 450 may cover the lateral surface of the substrate 410, the top and lateral surfaces of the encapsulant layer 430, and the top and exposed lateral surface of the metal bar 440. In some embodiments, before forming the shielding layer 450, a plurality of bumps 418 may be formed on the bottom wiring layer in the substrate 410, and the bumps 418 can be used to enable electrical connection between the electronic components in the electronic device with an exterior device or system.

The discussion herein included numerous illustrative figures that showed various portions of an electronic device and a method for making such electronic device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An electronic device, comprising:
a substrate;
at least one electronic component mounted on the substrate;
an encapsulant layer formed on the substrate and encapsulating the at least one electronic component;
at least one metal bar mounted on the substrate and protruding above the encapsulant layer; and
a shielding layer formed over the encapsulant layer, wherein the shielding layer is in contact with the at least one metal bar;
wherein the encapsulant layer comprises at least one trench each being adjacent to and extending around one of the at least one metal bar to expose an upper portion of a lateral surface of the metal bar from the encapsulant layer.

2. The electronic device of claim 1, wherein the substrate comprises a ground layer, and each of the at least one metal bar is electrically coupled to the ground layer.

3. The electronic device of claim 1, wherein the at least one electronic component comprises a wireless communication module.

4. The electronic device of claim 3, wherein the wireless communication module comprises a voltage-controlled oscillator circuit.

5. The electronic device of claim 1, wherein the at least one metal bar is higher than the at least one electronic component.

6. The electronic device of claim 1, wherein the at least one trench is formed using laser ablation.

7. The electronic device of claim 1, wherein each of the at least one trench comprises a sloping surface that slopes towards the metal bar.

8. A method for manufacturing an electronic device, wherein the method comprises:
providing a substrate with at least one electronic component and at least one metal bar mounted thereon;
forming an encapsulant layer on the substrate to encapsulate the at least one electronic component and the at least one metal bar and expose a top surface of each of the at least one metal bar;
forming at least one trench adjacent to and around the at least one metal bar, respectively, to expose an upper portion of a lateral surface of each of the at least one metal bar from the encapsulant layer; and
forming a shielding layer over the encapsulant layer and the at least one metal bar, wherein the shielding layer is in contact with the at least one metal bar.

9. The method of claim 8, wherein forming the encapsulant layer on the substrate comprises:
attaching a film on the top surface of each of the at least one metal bar or on a mold chase;
placing the mold chase over the substrate to form a molding chamber between the mold chase and the substrate, wherein the mold chase comprises at least one cavity accommodating the at least one metal bar, respectively, and the film is between the mold chase and the top surface of each of the at least one metal bar;
injecting into the molding chamber an encapsulant material;
solidifying the encapsulant material; and
detaching the films from the at least one metal bar to expose the respective top surface of the at least one metal bar.

10. The method of claim 9, wherein the films comprise a Teflon-based material.

11. The method of claim 8, wherein forming the at least one trench comprises:
forming the at least one trench using laser ablation.

12. The method of claim 8, wherein each of the at least one trench comprises a sloping surface that slopes towards the metal bar.

13. The method of claim 8, wherein the substrate comprises a ground layer, and each of the at least one metal bar is electrically coupled to the ground layer.

14. The method of claim 9, wherein the at least one electronic component comprises a wireless communication module.

15. The method of claim 14, wherein the wireless communication module comprises a voltage-controlled oscillator circuit.

16. The method of claim 8, wherein the at least one metal bar is higher than the at least one electronic component.
